(19) United States
(12) Patent Application Publication
(10) Pub. No.: US 2026/0242941 A1
(43) Pub. Date: Aug. 20, 2026

(54) EXHAUST DUCT COMPONENT AND SUBSTRATE PROCESSING APPARATUS

(71) Applicant: SCREEN Holdings Co., Ltd., Kyoto (JP)

(72) Inventors: Hironobu HODA, Kyoto-shi (JP); Hikaru FUJIWARA, Kyoto-shi (JP); Tomoe TAKI, Kyoto-shi (JP); Akihiko TAKI, Kyoto-shi (JP); Atsushi KUROEDA, Kyoto-shi (JP)

(21) Appl. No.: 19/541,334

(22) Filed: Feb. 16, 2026

(30) Foreign Application Priority Data
Feb. 19, 2025 (JP) 2025-024820

(51) Int. Cl. C23C 16/44; H10P 72/00

(52) U.S. Cl. CPC C23C 16/4412; H10P 72/0402

(57) ABSTRACT

An exhaust duct component is disposed around a substrate mounting part supporting or holding a substrate. The exhaust duct component includes flow passage components at N tiers. The flow passage components form internal flow passages into each of which a gas flows. Each of the flow passage components includes exhaust holes through which the gas flows into the internal flow passages. The exhaust holes of each of the flow passage components are arranged in a circumferential direction around the substrate mounting part. The exhaust duct component includes an exhaust outlet connected to a corresponding one of the internal flow passages at the most downstream tier. The gas flowing from an exhaust hole the closest to the exhaust outlet in the plan view at the most upstream tier flows away from the exhaust outlet through at least one of the internal flow passages in the circumferential direction.

### BACKGROUND

### Technical Field

The present disclosure relates to an exhaust duct component and a substrate processing apparatus.

### Description of the Background Art

Substrate processing apparatuses each processing a substrate have conventionally been proposed (Japanese Patent Application Laid-Open No. 2010-3958). For example, a substrate processing apparatus in Japanese Patent Application Laid-Open No. 2010-3958 includes a processing chamber, a susceptor, a showerhead, and a baffle plate. The susceptor is disposed in the processing chamber, and supports a substrate. The showerhead is disposed immediately above the susceptor in the processing chamber, and supplies a plasma toward the substrate. The baffle plate is disposed around the susceptor in the processing chamber. A plurality of exhaust holes are formed in the baffle plate. The exhaust holes penetrate the baffle plate in a vertical direction. Gas in an upper space of the processing chamber passes through the exhaust holes of the baffle plate, and flows into a lower space (an exhaust space) in the processing chamber. A vacuum pump draws the gas in the exhaust space out of the chamber to the outside.

### SUMMARY

An exhaust duct component is an exhaust duct component disposed around a substrate mounting part supporting or holding a substrate, the exhaust duct component including flow passage components at N tiers, the flow passage components being disposed around the substrate mounting part in a plan view, N being a natural number larger than or equal to 2, the flow passage components forming respective internal flow passages into each of which a gas flows, each of the flow passage components at the N tiers including a plurality of exhaust holes through which the gas flows into the internal flow passages, the exhaust holes of each of the flow passage components at the N tiers being arranged in a circumferential direction around the substrate mounting part in the plan view, the exhaust duct component including an exhaust outlet connected to a corresponding one of the internal flow passages at a most downstream tier among the N tiers, wherein the gas flowing from an exhaust hole closest to the exhaust outlet in the plan view among the exhaust holes at a most upstream tier among the N tiers flows away from the exhaust outlet through at least one of the internal flow passages at the N tiers in the circumferential direction.

A substrate processing apparatus includes: a chamber; the exhaust duct component disposed in the chamber; the substrate mounting part disposed in the chamber; a gas supply part that supplies a gas to the chamber; and an exhaust part that discharges the gas in the chamber through the exhaust outlet.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 is a diagram schematically illustrating an example structure of a substrate processing apparatus including an exhaust duct component according to Embodiment 1;

FIG. 2 is a plan view schematically illustrating an example structure of a flow passage component at the most upstream tier;

FIG. 3 is a perspective view schematically illustrating an example structure of a part of a flow passage component at the third tier;

FIG. 4 is a plan view schematically illustrating an example structure of the flow passage component at the third tier;

FIG. 5 is a plan view schematically illustrating an example structure of a flow passage component at the second tier;

FIG. 6 is a plan view schematically illustrating an example structure of a flow passage component at the first tier;

FIG. 7 is a perspective view schematically illustrating example gas flows in internal flow passages;

FIG. 8 is a perspective view schematically illustrating the first example structure of a part of a flow passage component according to Embodiment 2;

FIG. 9 is a plan view schematically illustrating the first example structure of the flow passage component according to Embodiment 2;

FIG. 10 is a plan view schematically illustrating the first example structure of the flow passage component according to Embodiment 2;

FIG. 11 is a plan view schematically illustrating the first example structure of the flow passage component according to Embodiment 2;

FIG. 12 is a perspective view schematically illustrating the second example structure of a part of the flow passage component according to Embodiment 2; and

FIG. 13 is a cross-sectional view schematically illustrating an example structure of flow passage components according to Embodiment 3.

### DESCRIPTION OF THE PREFERRED EMBODIMENTS

Under the technology of Japanese Patent Application Laid-Open No. 2010-3958, the gas flows into the exhaust holes of the baffle plate around the susceptor, and then flows into the exhaust space through the exhaust holes as described above. Then, the gas flows into an upstream port (an exhaust outlet) of an exhaust pipe connected to the exhaust space. For example, when the exhaust outlet is connected to a side portion of the exhaust space, route lengths between the exhaust holes of the baffle plate and the exhaust outlet have relatively large variations. Thus, there is a danger that flows of the gas passing through the exhaust holes of the baffle plate may vary between the exhaust holes. This results in variations in flow velocity distribution of the gas flowing above the substrate. Such variations in velocity may result in non-uniform processes on the substrates.

Thus, the present disclosure has an object of providing a technology that allows a gas to more uniformly flow.

Embodiments will be described in detail below with reference to drawings. It should be noted that dimensions and the number of parts are shown in exaggeration or in simplified form as appropriate for the sake of easier understanding. The same reference signs are assigned to parts having similar structures and functions, and overlapping description will be omitted in the following description.

In the following description, the same reference signs are assigned to the same constituent elements, and their names and functions are the same. Therefore, detailed description of such constituent elements may be omitted to avoid redundant description.

Even when the ordinal numbers such as “first” and “second” are used in the following description, these terms are used for convenience to facilitate the understanding of the details of Embodiments. The order that can be indicated by these ordinal numbers does not restrict the details of Embodiments.

Unless otherwise noted, the expressions indicating relative or absolute positional relationships (e.g., “in one direction”, “along one direction”, “parallel”, “orthogonal”, “central”, “concentric”, and “coaxial”) include those exactly indicating the positional relationships and those where an angle or a distance is relatively changed within tolerance or to the extent that similar functions can be obtained. Unless otherwise noted, the expressions indicating equality (e.g., “same”, “equal”, and “homogeneous”) include those indicating quantitatively exact equality and those in the presence of a difference within tolerance or to the extent that similar functions can be obtained. Unless otherwise noted, the expressions indicating shapes (e.g., “rectangular” or “cylindrical”) include those indicating geometrically exact shapes and those indicating, for example, roughness or a chamfer to the extent that similar advantages can be obtained. An expression “comprising”, “including”, “containing”, or “having” one constituent element is not an exclusive expression for excluding the presence of the other constituent elements. An expression “at least one of A, B, and C” involves only A, only B, only C, any two of A, B, and C, and all of A, B, and C.

### Embodiment 1

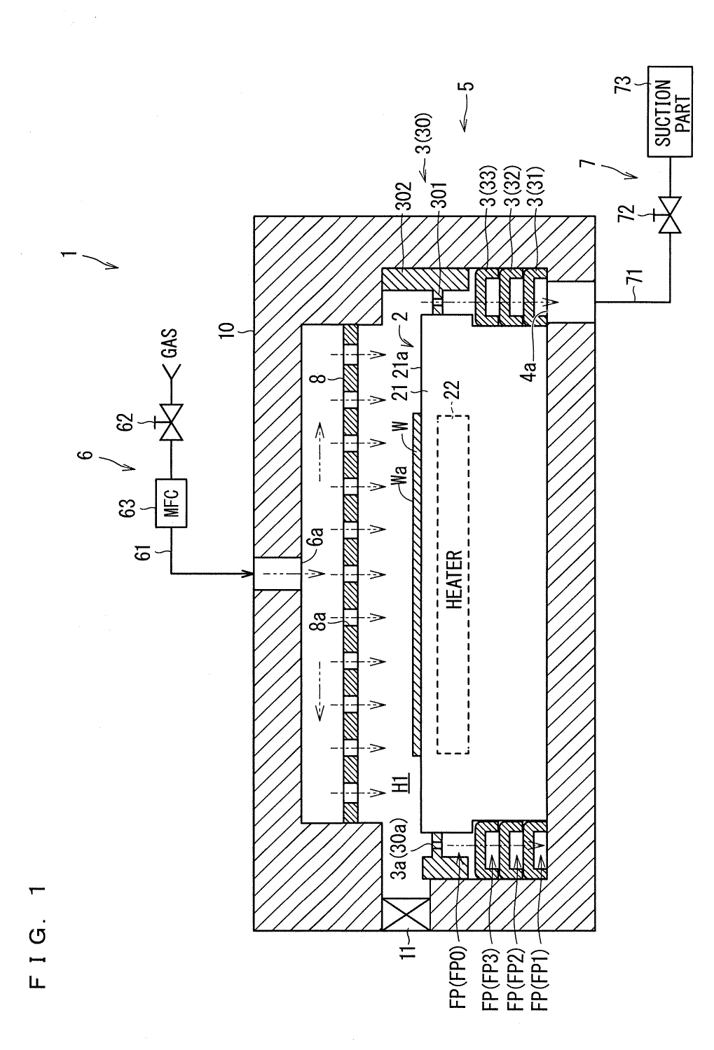

FIG. 1 is a diagram schematically illustrating an example structure of a substrate processing apparatus 1 including an exhaust duct component 5 according to Embodiment 1. The substrate processing apparatus 1 is a single-wafer processing apparatus that processes substrates W one by one. Examples of the substrates W include a semiconductor wafer, a liquid crystal display substrate, an organic electroluminescence (EL) substrate, a flat panel display (FPD) substrate, an optical display substrate, a magnetic disk substrate, an optical disk substrate, a magneto-optical disk substrate, a photomask substrate, and a solar cell substrate. The substrates W have a thin plate shape. In the following, the substrates W are semiconductor wafers. For example, the substrates W are silicon substrates. The substrates W are, for example, disk-shaped. Each of the substrates W has a diameter of, for example, approximately 300 mm, and has a thickness of, for example, approximately more than or equal to 0.5 mm and less than or equal to 3 mm.

As illustrated in FIG. 1, the substrate processing apparatus 1 includes a chamber 10, a substrate mounting part 2, the exhaust duct component 5, a gas supply part 6, and an exhaust part 7.

The chamber 10 has a box shape. An internal space H1 of the chamber 10 corresponds to a processing space in which the substrates W are processed. The chamber 10 is switchable between a loading/unloading state in which the internal space H1 is connected in communication with an external space and a sealed state in which the internal space H1 is shielded from the external space. For example, an openable and closeable loading/unloading entrance 11 may be disposed in a sidewall of the chamber 10. The loading/unloading entrance 11 is, for example, a shutter or a gate valve. Opening the loading/unloading entrance 11 sets the chamber 10 in the loading/unloading state, whereas closing the loading/unloading entrance 11 sets the chamber 10 in the sealed state. When the chamber 10 is in the loading/unloading state, a transport robot that is disposed in the external space and is not illustrated loads the substrates W into the chamber 10, and unloads the substrates W from the chamber 10. When the chamber 10 is in the sealed state, the substrate processing apparatus 1 performs processes on the substrates W in the internal space H1 of the chamber 10.

The substrate mounting part 2 is disposed in the chamber 10. The substrate mounting part 2 supports or holds the substrate W in a horizontal attitude. The horizontal attitude herein is an attitude in which the thickness direction of the substrate W is along the vertical direction. The substrate mounting part 2 may be a mount that supports the substrate W. In the example of FIG. 1, the substrate mounting part 2 includes a stage 21 and a heater 22. The stage 21 has an upper surface 21a, and the substrate W is placed on the upper surface 21a. In the example of FIG. 1, while the substrate W is placed on the substrate mounting part 2, a main surface Wa (e.g., an upper surface) of the substrate W is exposed in the internal space H1 of the chamber 10. In the example of FIG. 1, the upper surface 21a of the stage 21 is parallel to a horizontal plane, and is wider than the substrate W. The upper surface 21a of the stage 21 is, for example, of a circular shape in a plan view. The plan view herein means viewing an object while a gaze is along the vertical direction. The heater 22 heats the substrate W on the stage 21. The heater 22 may be, for example, an electric resistance heater with an electric heating wire. The heater 22 may be included in the stage 21.

The gas supply part 6 supplies a gas to the chamber 10. The gas includes, for example, a processing gas. The processing gas supplied to the chamber 10 acts on the main surface Wa (e.g., the upper surface) of the substrate W. Through the action, the main surface Wa of the substrate W is subjected to a process corresponding to the type of the processing gas. Examples of the processing gas may include hydrogen fluoride gas and ozone gas. Hydrogen fluoride gas can etch an oxide film (e.g., a silicon oxide film) of the main surface Wa of the substrate W. Ozone gas can oxidatively remove an organic matter on the main surface Wa of the substrate W.

In the example of FIG. 1, the gas supply part 6 includes a supply pipe 61, a supply valve 62, and a flow rate regulator 63. A downstream end of the supply pipe 61 is connected to, for example, a ceiling of the chamber 10, and an upstream end of the supply pipe 61 is connected to a gas supply source. The gas supply source causes the gas to flow into the upstream end of the supply pipe 61. The supply valve 62 is disposed in the supply pipe 61, and switches between opening and closing of the supply pipe 61. The flow rate regulator 63 is disposed in the supply pipe 61, and regulates a flow rate of the gas flowing through the supply pipe 61. The flow rate regulator 63 is, for example, a massflow controller.

In the example of FIG. 1, a rectifier plate 8 is disposed in the internal space H1 of the chamber 10. The rectifier plate 8 is plate-shaped, and is disposed in an attitude such that its thickness direction is along the vertical direction. The rectifier plate 8 is disposed above the substrate mounting part 2, and faces the substrate mounting part 2 in the vertical direction. The rectifier plate 8 includes a plurality of openings 8a. The openings 8a penetrate the rectifier plate 8 in the vertical direction. The openings 8a are two-dimensionally distributed in a plan view.

In the example of FIG. 1, the gas flows into the internal space H1 through a gas supply port 6a (the downstream end of the supply pipe 61) at the ceiling of the chamber 10. In the example of FIG. 1, the gas supply port 6a is provided at a position aligned with the substrate mounting part 2 in the vertical direction. As a specific example, the gas supply port 6a is provided at a position aligned with the center of the substrate W on the stage 21 in the vertical direction. The gas is rectified by passing through the openings 8a of the rectifier plate 8. The rectified gas flows toward the main surface Wa of the substrate W. In the example of FIG. 1, flows of the gas are schematically illustrated by double dot-dashed arrows.

The gas supply part 6 may selectively supply gases of a plurality of types. For example, the gas supply part 6 may selectively supply the processing gas and an inert gas. Examples of the inert gas include at least one of nitrogen gas and a noble gas. Examples of the noble gas include argon gas.

The exhaust duct component 5 is disposed in the chamber 10. As a specific example, the exhaust duct component 5 is disposed to surround the substrate mounting part 2 in a plan view. The exhaust duct component 5 includes internal flow passages FP at N tiers connected in communication with each other. N is a natural number larger than or equal to 2. As illustrated in FIG. 1, the exhaust duct component 5 also includes a plurality

of exhaust holes 30a and an exhaust outlet 4a. The exhaust holes 30a are arranged to surround the substrate mounting part 2 in a plan view. In the example of FIG. 1, the exhaust outlet 4a is disposed at a lower portion of the exhaust duct component 5. The gas supplied to the main surface Wa of the substrate W flows outward in the radial direction along the main surface Wa of the substrate W, and flows into the exhaust holes 30a of the exhaust duct component 5. The respective gases flow through the internal flow passages FP at the N tiers in order and flow into the exhaust outlet 4a.

In the example of FIG. 1, the single exhaust outlet 4a is provided at a position aligned with a part of the exhaust duct component 5 in the vertical direction. Thus, direct distances between the exhaust holes 30a around the substrate mounting part 2 and the exhaust outlet 4a vary between the exhaust holes 30a. The exhaust duct component 5 is a component for reducing variations in the lengths of gas routes (hereinafter referred to as route lengths) from the exhaust holes 30a to the exhaust outlet 4a, which will be described later. An example specific structure of the exhaust duct component 5 will be described later in detail.

The exhaust part 7 discharges a gas in the chamber 10 to the outside through the exhaust outlet 4a. In the example of FIG. 1, the exhaust part 7 includes an exhaust pipe 71. An upstream end of the exhaust pipe 71 is connected to the exhaust outlet 4a. The gas flows into the exhaust pipe 71 through the exhaust outlet 4a. An exhaust valve 72 is disposed in the exhaust pipe 71. The exhaust valve 72 switches between opening and closing of the exhaust pipe 71. As illustrated in FIG. 1, the exhaust part 7 may further include a suction part 73. The suction part 73 is connected to the exhaust pipe 71. The suction part 73 suctions a gas from the chamber 10 through the exhaust pipe 71. The suction part 73 may be a fan or a pump (e.g., a vacuum pump).

Next, an example of a more specific structure of the exhaust duct component 5 will be described. The exhaust duct component 5 includes flow passage components 3 at the N tiers. The flow passage components 3 at the N tiers are stacked in the vertical direction around the substrate mounting part 2. In other words, the flow passage components 3 at the N tiers are aligned in the vertical direction. In the example of FIG. 1, the flow passage components 3 at four tiers are provided. In Embodiment 1, the flow passage component 3 that is the closest to the exhaust outlet 4a is the flow passage component 3 at the first tier, and the flow passage component 3 that is the closest to the gas supply port 6a is the flow passage component 3 at the N-th tier. The first tier corresponds to the most downstream tier, and the N-th tier corresponds to the most upstream tier. Hereinafter, the flow passage component 3 at the first tier (i.e., the most downstream tier) will be referred to as a flow passage component 31, the flow passage component 3 at the second tier will be referred to as a flow passage component 32, the flow passage component 3 at the third tier will be referred to as a flow passage component 33, and the flow passage component 3 at the most upstream tier will be referred to as a flow passage component 30.

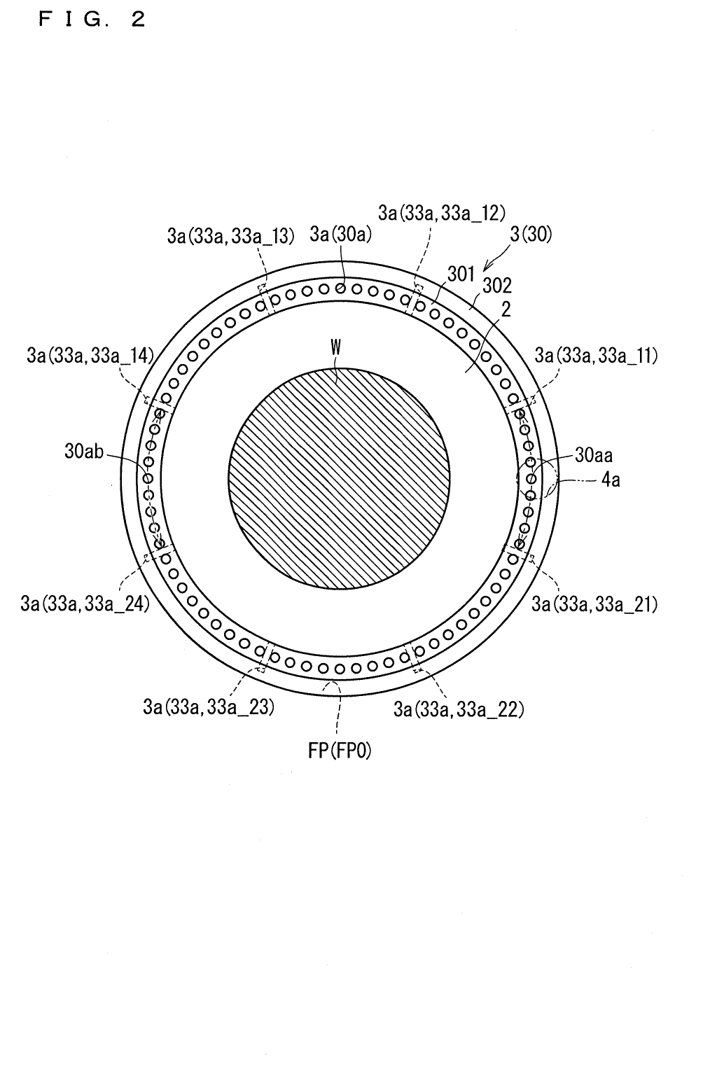

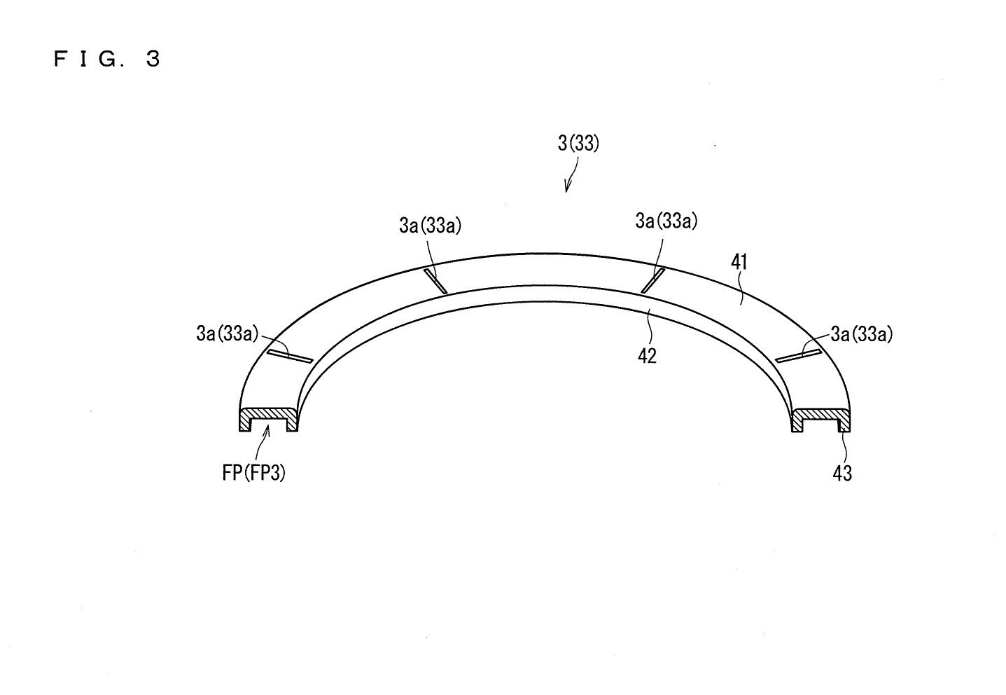

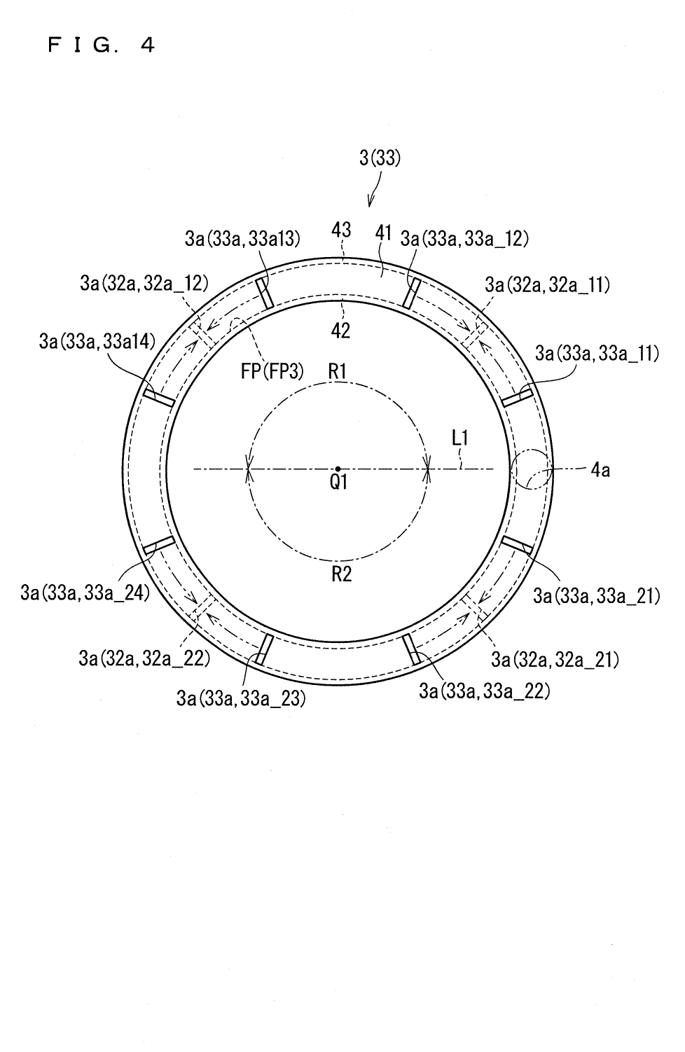

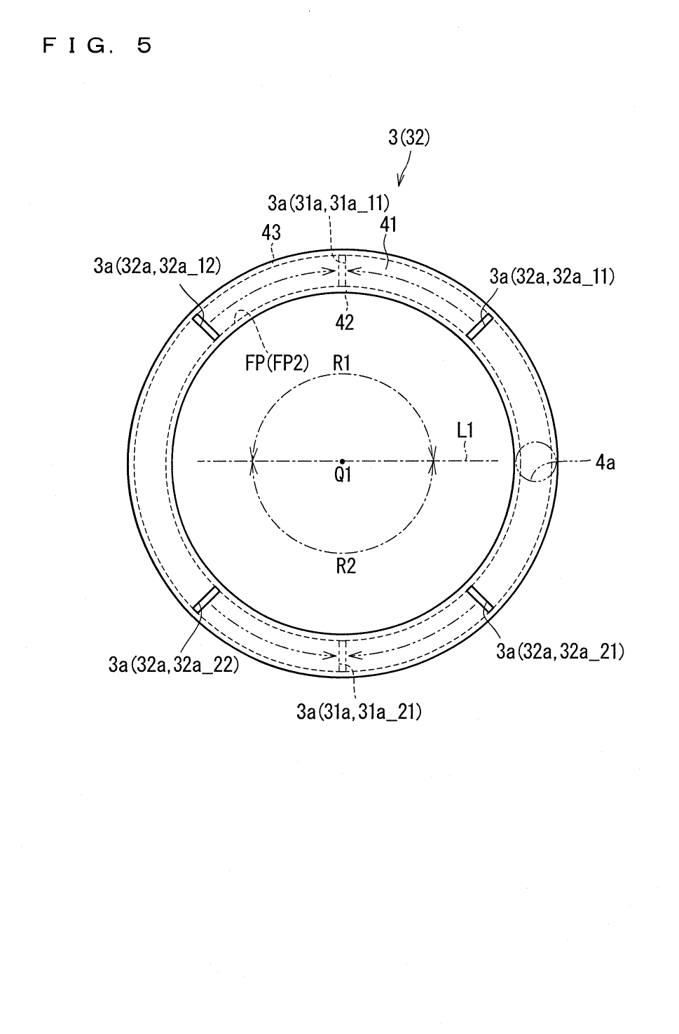

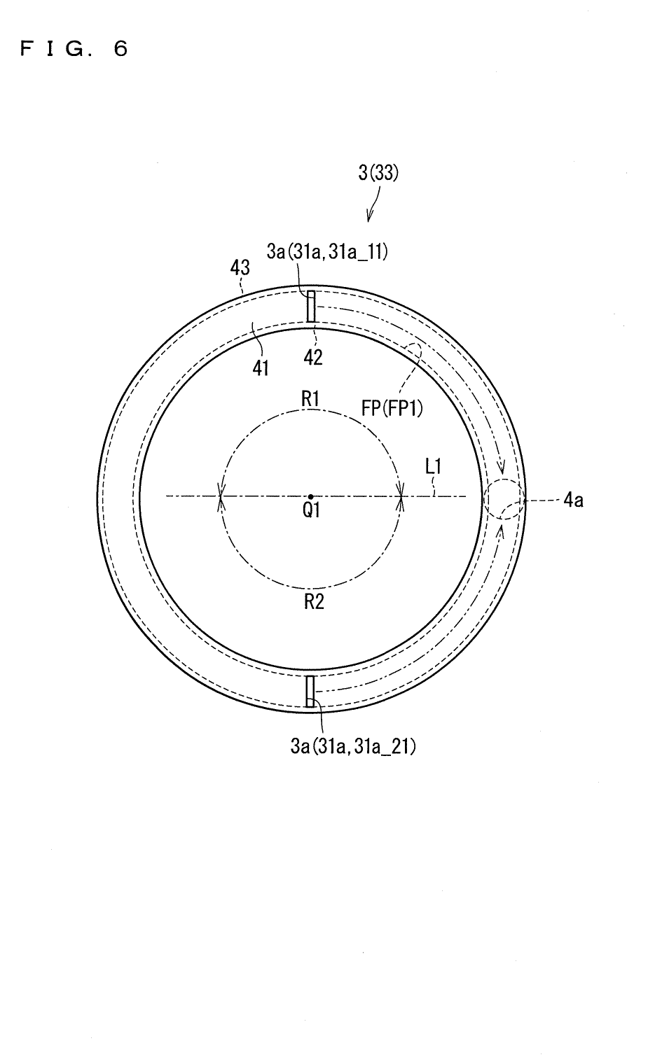

FIG. 2 is a plan view schematically illustrating an example structure of the flow passage component 30 at the most upstream tier. FIG. 3 is a perspective view schematically illustrating an example structure of a part of the flow passage component 33 at the third tier. FIG. 4 is a plan view schematically illustrating the example structure of the flow passage component 33 at the third tier. FIG. 5 is a plan view schematically illustrating an example structure of the flow passage component 32 at the second tier. FIG. 6 is a plan view schematically illustrating an example structure of the flow passage component 31 at the first tier.

The flow passage components 3 at the respective tiers are components for forming the internal flow passages FP at the respective tiers. Hereinafter, the internal flow passage FP formed by the flow passage component 30 at the most upstream tier will also be referred to as an internal flow passage FP0, the internal flow passage FP formed by the flow passage component 33 at the third tier will also be referred to as an internal flow passage FP3, the internal flow passage FP formed by the flow passage component 32 at the second tier will also be referred to as an internal flow passage FP2, and the internal flow passage FP formed by the flow passage component 31 at the first tier will also be referred to as an internal flow passage FP1.

Each of the flow passage components 3 includes a plurality of exhaust holes 3a. Hereinafter, the exhaust holes 3a of the flow passage component 30 at the most upstream tier will also be referred to as exhaust holes 30a, the exhaust holes 3a of the flow passage component 33 at the third tier will also be referred to as exhaust holes 33a, the exhaust holes 3a of the flow passage component 32 at the second tier will also be referred to as exhaust holes 32a, and the exhaust holes 3a of the flow passage component 31 at the first tier will also be referred to as exhaust holes 31a. The exhaust holes 3a at the n-th tier except the most upstream tier (1 ≤ n < N herein) function as openings for connecting the internal flow passage FP at the (n + 1)-th tier to the internal flow passage FP at the n-th tier.

As seen from FIG. 1, the flow passage component 3 at the n-th tier may form the internal flow passage FP at the n-th tier together with the flow passage component 3 at the (n - 1)-th tier. In the example of FIG. 1, the flow passage component 30 at the most upstream tier includes a plate portion 301 and an outer circumferential portion 302. The plate portion 301 is of a ring plate shape surrounding the substrate mounting part 2. In the example of FIG. 2, the plate portion 301 is of an annular shape concentric with the substrate W placed on the substrate mounting part 2. The plate portion 301 is disposed in an attitude such that its thickness direction is along the vertical direction. In the example of FIG. 1, an inner peripheral edge of the plate portion 301 is in contact with the side surface of the substrate mounting part 2.

The plate portion 301 includes the plurality of exhaust holes 30a. The exhaust holes 30a penetrate the plate portion 301 in the vertical direction. The exhaust holes 30a are arranged at intervals along a circumferential direction around the substrate mounting part 2. The circumferential direction around the substrate mounting part 2 herein is a circumferential direction with respect to the center of the substrate W. In the example of FIG. 1, the exhaust holes 30a are arranged at equal intervals in the circumferential direction. Each of the exhaust holes 30a may be circular in a plan view. The number of the exhaust holes 30a can be appropriately set, and may be, for example, 20 or more or 30 or more. The diameter of the exhaust hole 30a may be, for example, approximately several mm.

The outer circumferential portion 302 is disposed closer to the outer circumference than the plate portion 301. In the example of FIG. 2, the outer circumferential portion 302 is ring-shaped (e.g., of an annular shape). The outer circumferential portion 302 may be thicker than the plate portion 301. The outer circumferential portion 302 can be fixed to an inner circumferential surface of the chamber 10.

Here, an example of a position of the plate portion 301 in the vertical direction, that is, positions of the exhaust holes 30a in the vertical direction will be described. In the example of FIG. 1, the main surface (e.g., the upper surface) of the plate portion 301 which is closer to the gas supply port 6a is located closer to the exhaust outlet 4a with respect to the main surface Wa of the substrate W on the substrate mounting part 2. In the example of FIG. 1, the upper surface of the plate portion 301 is located below the main surface Wa of the substrate W. Furthermore, in the example of FIG. 1, the upper surface 21a of the stage 21 is wider than the main surface Wa of the substrate W. In this case, the main surface of the plate portion 301 may be located closer to the exhaust outlet 4a with respect to the upper surface 21a of the stage 21. In other words, the upper surface of the plate portion 301 may be located below the upper surface 21a of the stage 21. This allows the gas to smoothly flow through the main surface Wa of the substrate W, the peripheral edge of the substrate W, the upper surface 21a of the stage 21, and the peripheral edge of the stage 21 in a stepwise manner, and flow into the exhaust holes 30a.

The exhaust holes 30a are connected to the internal flow passage FP0, and the gas flows into the internal flow passage FP0 through the exhaust holes 30a. In the example of FIG. 1, the internal flow passage FP0 is formed by the flow passage component 30 at the most upstream tier, a portion of the side surface of the substrate mounting part 2, a portion of the inner circumferential surface of the chamber 10, and the flow passage component 33 at the third tier (a plate portion 41 to be described later). Thus, the flow passage component 30 can also be understood as including the plate portion 301, the outer circumferential portion 302, the portion of the side surface of the substrate mounting part 2, and the portion of the inner circumferential surface of the chamber 10. Here, the portion of the side surface of the substrate mounting part 2 is a portion of the side surface between the plate portion 301 and the flow passage component 33. The portion of the inner circumferential surface of the chamber 10 is a portion of the inner circumferential surface between the outer circumferential portion 302 and the flow passage component 32. The internal flow passage FP0 is of a ring shape surrounding the substrate mounting part 2.

The respective gases that flow into the exhaust holes 30a flow through the internal flow passages FP at a plurality of tiers in order and flow into the exhaust outlet 4a, as will be described later. Here, an exhaust hole 30aa that is the closest to the exhaust outlet 4a among the exhaust holes 30a in a plan view will be considered with reference to FIG. 2. In the example of FIG. 2, the exhaust hole 30aa overlaps the exhaust outlet 4a in a plan view. In other words, the exhaust hole 30aa is located immediately above the exhaust outlet 4a. The gas flowing into the exhaust hole 30aa flows away from the exhaust outlet 4a through

at least one of the internal flow passages FP at the plurality of tiers in the exhaust duct component 5 along the circumferential direction. In the example of FIG. 2, flows of the gas in the internal flow passage FP0 which has flown into the exhaust hole 30aa are schematically illustrated by double dot-dashed arrows using the exhaust hole 30aa a starting point. In the example of FIG. 2, the gas from the exhaust hole 30aa flows away from the exhaust outlet 4a through the internal flow passage FP0 as will be described later in detail. Thus, the route length from the exhaust hole 30aa to the exhaust outlet 4a is prolonged. Consequently, the route length on the exhaust hole 30aa can be brought closer to the route length on another exhaust hole 30a. In other words, variations in the route length can be reduced.

Next, an exhaust hole 30ab that is the furthest from the exhaust outlet 4a among the exhaust holes 30a in a plan view will be considered. The exhaust hole 30ab is one of the exhaust holes 30a that is opposite to the exhaust hole 30aa with respect to the substrate W. The gas flowing into the exhaust hole 30ab may flow through the internal flow passages FP at all the tiers along the circumferential direction to approach the exhaust outlet 4a. In FIG. 2, flows of the gas which has flown into the exhaust hole 30ab in the internal flow passage FP0 are schematically illustrated by double dot-dashed arrows using the exhaust hole 30ab as a starting point. In the example of FIG. 2, the gas from the exhaust hole 30ab flows through the internal flow passage FP0 in the circumferential direction to approach the exhaust outlet 4a as will be described later in detail. Furthermore, the gas flows through the internal flow passage FP at the downstream tier to approach the exhaust outlet 4a as will be described later in detail. This can avoid an increase in the route length on the exhaust hole 30ab that is the furthest from the exhaust outlet 4a. Thus, the variations in the route length can further be reduced.

The flow of the gas in the internal flow passage FP0 at the most upstream tier is determined by the positions of the exhaust holes 30a at the most upstream tier and the positions of the exhaust holes 33a at the next third tier. Here, the flow passage component 33 at the third tier will be described. In the examples of FIGS. 3 and 4, the flow passage component 33 at the third tier includes the plate portion 41, an inner circumferential wall 42, and an outer circumferential wall 43. The plate portion 41 is plate-shaped, and is disposed in a state such that its thickness direction is along the vertical direction. In the example of FIG. 4, the plate portion 41 is of a ring shape surrounding the substrate mounting part 2. As a specific example, the plate portion 41 is of an annular shape concentric with the substrate W placed on the substrate mounting part 2. The plate portion 41 functions as a partition part for partitioning the internal flow passage FP0 at the most upstream tier and the internal flow passage FP3 at the third tier.

The plate portion 41 includes the plurality of exhaust holes 33a. The exhaust holes 33a penetrate the plate portion 41 of the flow passage component 33 in the vertical direction. Each of the exhaust holes 33a functions as an opening that connects the internal flow passage FP0 to the internal flow passage FP3. The exhaust holes 33a are arranged in the circumferential direction. In the example of FIG. 4, all the exhaust holes 33a are located at positions clear of the exhaust outlet 4a in a plan view. In other words, all the exhaust holes 33a are located without any overlap with the exhaust outlet 4a in a plan view in the example of FIG. 4. Since the exhaust hole 30aa overlaps the exhaust outlet 4a in a plan view as described above (see also FIG. 2), the exhaust holes 33a at the third tier are located at the positions clear of the exhaust hole 30aa.

In the example of FIG. 4, the exhaust holes 33a are arranged at equal intervals in the circumferential direction. In the example of FIG. 4, the number of the exhaust holes 33a at the third tier is less than that of the exhaust holes 30a at the most upstream tier, and is, for example, 8. In other words, the number of the exhaust holes 33a at the n (= 3)-th tier is two to the power of n (= 8) in the example of FIG. 4.

Here, a first arc region R1 and a second arc region R2 are introduced. The first arc region R1 and the second arc region R2 are regions obtained by dividing a virtual circle concentric with the substrate W into two by a virtual line L1 passing through the exhaust outlet 4a and the center Q1 of the virtual circle. Hereinafter, the exhaust holes 33a located in the first arc region R1 will be referred to as an exhaust hole 33a_11, an exhaust hole 33a_12, an exhaust hole 33a_13, and an exhaust hole 33a_14 in order of proximity to the exhaust outlet 4a. In other words, the exhaust hole 33a_11 is the closest to the exhaust outlet 4a, and the exhaust hole 33a_14 is the furthest from the exhaust outlet 4a in the first arc region R1. Similarly, the exhaust holes 33a located in the second arc region R2 will be referred to as an exhaust hole 33a_21, an exhaust hole 33a_22, an exhaust hole 33a_23, and an exhaust hole 33a_24 in order of proximity to the exhaust outlet 4a. In other words, the exhaust hole 33a_21 is the closest to the exhaust outlet 4a, and the exhaust hole 33a_24 is the furthest from the exhaust outlet 4a in the second arc region R2. In the example of FIG. 4, the exhaust holes 33a in the first arc region R1 and the exhaust holes 33a in the second arc region R2 are symmetric with respect to the virtual line L1.

Here, an example flow of the gas in the internal flow passage FP0 at the most upstream tier will be described again with reference to FIG. 2. The gas flowing into the exhaust holes 30a at the most upstream tier flows through the internal flow passage FP0 toward the exhaust holes 33a at the third tier that are mainly the closest to the internal flow passage FP0 itself. In other words, when attention is given to a single exhaust hole 33a, gases flowing into the exhaust holes 30a located near this exhaust hole 33a flow through the internal flow passage FP0 toward the exhaust hole 33a. This allows the gases from the exhaust holes 30a to merge and flow into the single exhaust hole 33a.

The exhaust hole 30aa at the most upstream tier which is the closest to the exhaust outlet 4a is located between the exhaust hole 33a_11 and the exhaust hole 33a_21 at the third tier in a plan view. Here, the exhaust hole 30aa is, for example, equidistant from the exhaust hole 33a_11 and the exhaust hole 33a_21. Thus, the gas from the exhaust hole 30aa flows through the internal flow passage FP0 in the circumferential direction toward each of the exhaust hole 33a_11 and the exhaust hole 33a_21 that are the closest to the exhaust hole 30aa. In other words, the gas from the exhaust hole 30aa flows away from the exhaust outlet 4a through the internal flow passage FP0 (the double dot-dashed arrows in FIG. 2). This can extend the route length of the gas flowing into the exhaust hole 30aa that is closer to the exhaust outlet 4a.

In the example of FIG. 2, the exhaust hole 30ab at the most upstream tier which is the furthest from the exhaust outlet 4a is located at a position clear of the exhaust holes 30a at the third tier in a plan view. Specifically, the exhaust hole 30ab is located between the exhaust hole 33a_14 and the exhaust hole 33a_24. Here, the exhaust hole 30ab is, for example, equidistant from the exhaust hole 33a_14 and the exhaust hole 33a_24. Thus, the gas from the exhaust hole 30ab flows through the internal flow passage FP0 toward each of the exhaust hole 33a_14 and the exhaust hole 33a_24. In other words, the gas from the exhaust hole 30ab flows through the internal flow passage FP0 in the circumferential direction to approach the exhaust outlet 4a. This can avoid an increase in the route length of the gas flowing into the exhaust hole 30ab that is far from the exhaust outlet 4a.

Next, the internal flow passage FP3 at the third tier will be described. In the example of FIG. 1, the internal flow passage FP3 at the third tier is formed by the flow passage component 33 at the third tier and the flow passage component 32 at the second tier. In the flow passage component 33 at the third tier, the inner circumferential wall 42 is disposed at an end (the inner circumferential edge) of the plate portion 41 which is closer to the inner circumference, and the outer circumferential wall 43 is disposed at an end (the outer circumferential edge) of the plate portion 41 which is closer to the outer circumference (see also FIG. 3). The inner circumferential wall 42 and the outer circumferential wall 43 protrude from the plate portion 41 in the vertical direction (downward herein). In the example of FIG. 4, each of the inner circumferential wall 42 and the outer circumferential wall 43 is of an annular shape concentric with the substrate W on the substrate mounting part 2. The inner circumferential wall 42 is, for example, identical in height width to the outer circumferential wall 43. Lower ends of the inner circumferential wall 42 and the outer circumferential wall 43 at the third tier can be in contact with the flow passage component 32 (specifically, the plate portion 41) at the second tier. The flow passage component 33 at the third tier may be placed on the flow passage component 32 at the second tier, and may be fixed to the flow passage component 32.

The gas flows from the internal flow passage FP0 into the internal flow passage FP3 at the next tier through the exhaust holes 30a. The gas flowing into each of the exhaust hole 33a_11 and the exhaust hole 33a_21 that are the closest to the exhaust outlet 4a may flow away from the exhaust outlet 4a through at least one of the internal flow passages FP at the third tier or below in the circumferential direction. In other words, the positions of the exhaust holes 3a at the third tier or below may be defined to implement this flow.

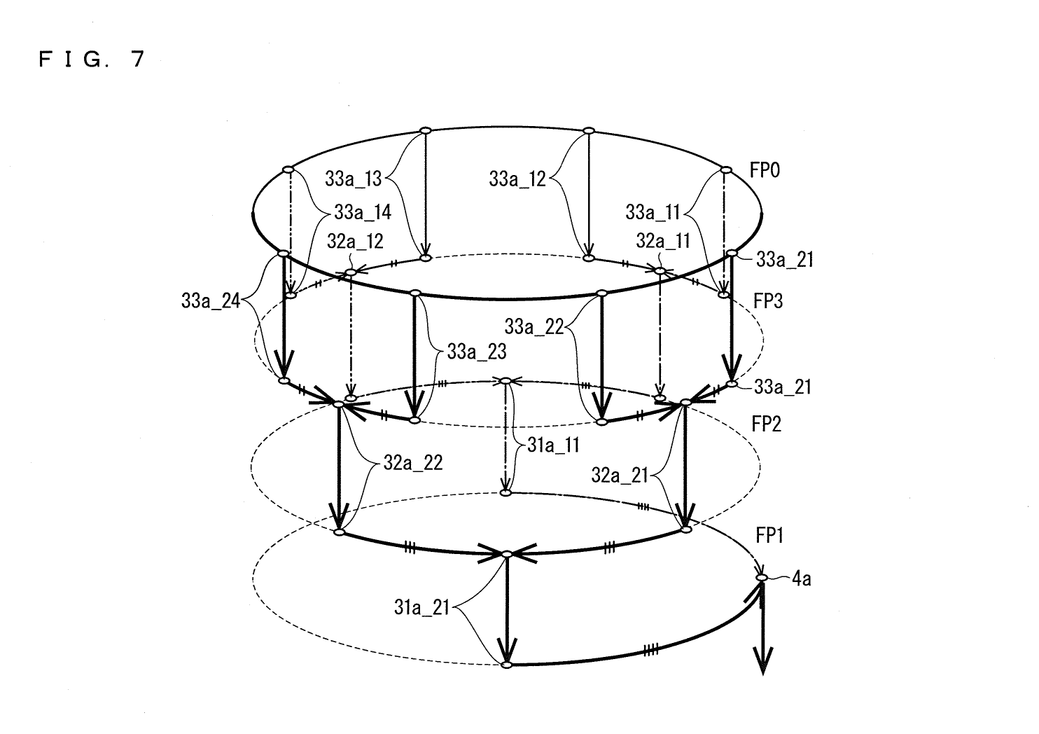

FIG. 7 is a perspective view schematically illustrating example gas flows in the internal flow passages FP. For example, a route of the gas flowing into the exhaust hole 33a_11 will be described. FIG. 7 illustrates this route of the gas using alternate long and short dashed lines. In other words, the gas from the exhaust hole 33a_11 flows away from the exhaust outlet 4a through the internal flow passage FP3 at the third tier and the internal flow passage FP2 at the second tier in the circumferential direction, and flows toward the exhaust outlet 4a through the internal flow passage FP1 at the first tier in the circumferential direction. Similarly, the gas from the exhaust hole 33a_21 flows away from the exhaust outlet 4a through the internal flow passage FP3 at the third tier and the internal flow passage FP2 at the second tier in the circumferential direction, and flows toward the exhaust outlet 4a through the internal flow passage FP1 at the first tier in the circumferential direction.

The gas flowing into each of the exhaust hole 33a_14 and the exhaust hole 33a_24 that are the furthest from the exhaust outlet 4a may flow through all the internal flow passages FP at the third tier and below in the circumferential direction to approach the exhaust outlet 4a. In other words, the positions of the exhaust holes 3a at the third tier or below may be defined to implement this flow. In the example of FIG. 7, the gas from the exhaust hole 33a_14 flows from the internal flow passage FP at the third tier to the internal flow passage FP1 at the first tier to approach the exhaust outlet 4a (see also double dot-dashed arrows).

Specific examples of the flow passage components 3 will be described in detail below.

In the example of FIG. 5, the flow passage component 32 at the second tier includes the plate portion 41, the inner circumferential wall 42, and the outer circumferential wall 43, similarly to the flow passage component 33 at the third tier. The plate portion 41 of the flow passage component 32 at the second tier functions as a partition part for partitioning the internal flow passage FP3 at the third tier and the internal flow passage FP2 at the second tier. The plate portion 41 of the flow passage component 32 includes the plurality of exhaust holes 32a. The exhaust holes 32a penetrate the plate portion 41 of the flow passage component 32 in the vertical direction. Each of the exhaust holes 32a functions as an opening that connects the internal flow passage FP3 to the internal flow passage FP2. In the example of FIG. 5, all the exhaust holes 32a are located at

positions clear of the exhaust outlet 4a in a plan view. In other words, none of the exhaust holes 32a overlaps the exhaust outlet 4a in a plan view in the example of FIG. 5. In the example of FIG. 5, the exhaust holes 32a are arranged at equal intervals in the circumferential direction. In the example of FIG. 5, the exhaust holes 32a at the second tier are fewer in number than the exhaust holes 33a at the third tier. The number of the exhaust holes 32a is four as a specific example. In other words, the number of the exhaust holes 32a at the n (= 2)-th tier is two to the power of n (= 4) in the example of FIG. 5.

Hereinafter, the exhaust holes 32a located in the first arc region R1 will be referred to as an exhaust hole 32a_11 and an exhaust hole 32a_12 in order of proximity to the exhaust outlet 4a. In other words, the exhaust hole 32a_11 is the closest to the exhaust outlet 4a, and the exhaust hole 32a_12 is the furthest from the exhaust outlet 4a in the first arc region R1. Similarly, the exhaust holes 32a located in the second arc region R2 will be referred to as an exhaust hole 32a_21 and an exhaust hole 32a_22 in order of proximity to the exhaust outlet 4a. In other words, the exhaust hole 32a_21 is the closest to the exhaust outlet 4a, and the exhaust hole 32a_22 is the furthest from the exhaust outlet 4a in the second arc region R2.

With reference to FIG. 4, the exhaust holes 32a at the second tier and the exhaust holes 33a at the third tier are provided at different positions in a plan view. Furthermore, all the exhaust holes 32a at the second tier are provided at positions clear of a region between the exhaust holes 33a_11 and the exhaust hole 33a_21 at the third tier in the example of FIG. 4. In other words, in the example of FIG. 4, all the exhaust holes 32a at the second tier are provided opposite to the exhaust outlet 4a with respect to the exhaust hole 33a_11 at the third tier in the first arc region R1, and all the exhaust holes 32a at the second tier are provided opposite to the exhaust outlet 4a with respect to the exhaust hole 33a_21 at the third tier in the second arc region R2. In the example of FIG. 4, the exhaust

hole 32a_11 at the second tier is provided between the exhaust hole 33a_11 and the exhaust hole 33a_12 at the third tier in the first arc region R1, and the exhaust hole 32a_21 at the second tier is provided between the exhaust hole 33a_21 and the exhaust hole 33a_22 at the third tier in the second arc region R2. As a specific example, the exhaust hole 32a_11 at the second tier is located at the center between the exhaust hole 33a_11 and the exhaust hole 33a_12 at the third tier, and the exhaust hole 32a_21 at the second tier is located at the center between the exhaust hole 33a_21 and the exhaust hole 33a_22 at the third tier.

This allows the gas flowing into the exhaust hole 33a_11 at the third tier to flow through the internal flow passage FP3 toward the exhaust hole 32a_11 at the second tier in the circumferential direction. In other words, the gas from the exhaust hole 33a_11 closer to the exhaust outlet 4a flows away from the exhaust outlet 4a through the internal flow passage FP3 in a plan view. This can extend the route length from the exhaust hole 33a_11 to the exhaust outlet 4a. Similarly, the gas flowing into the exhaust hole 33a_21 closer to the exhaust outlet 4a flows through the internal flow passage FP3 toward the exhaust hole 32a_21 at the second tier in the circumferential direction. In other words, the gas from the exhaust hole 33a_21 flows away from the exhaust outlet 4a through the internal flow passage FP3. This can extend the route length from the exhaust hole 33a_21 to the exhaust outlet 4a.

Furthermore, all the exhaust holes 32a at the second tier are provided at positions clear of a region between the exhaust holes 33a_14 and the exhaust hole 33a_24 at the third tier in the example of FIG. 4. In other words, in the example of FIG. 4, all the exhaust holes 32a at the second tier are provided closer to the exhaust outlet 4a with respect to the exhaust hole 33a_14 at the third tier in the first arc region R1, and all the exhaust holes 32a at the second tier are provided closer to the exhaust outlet 4a with respect to the exhaust hole 33a_24 in the second arc region R2. In the example of FIG. 4, the exhaust hole 32a_12 at the second tier is provided between the exhaust hole 33a_13 and the exhaust hole 33a_14 at the third tier in the first arc region R1, and the exhaust hole 32a_22 at the second tier is provided between the exhaust hole 33a_23 and the exhaust hole 33a_24 at the third tier in the second arc region R2. As a specific example, the exhaust hole 32a_12 at the second tier is located at the center between the exhaust hole 33a_13 and the exhaust hole 33a_14 at the third tier, and the exhaust hole 32a_22 at the second tier is located at the center between the exhaust hole 33a_23 and the exhaust hole 33a_24 at the third tier.

This allows the gas flowing into the exhaust hole 33a_14 to flow through the internal flow passage FP3 toward the exhaust hole 32a_12 at the second tier in the circumferential direction. In other words, the gas from the exhaust hole 33a_14 far from the exhaust outlet 4a flows through the internal flow passage FP3 to approach the exhaust outlet 4a in a plan view. This can avoid an increase in the route length from the exhaust hole 33a_14 to the exhaust outlet 4a. Similarly, the gas flowing into the exhaust hole 33a_24 flows through the internal flow passage FP3 toward the exhaust hole 32a_22 at the second tier in the circumferential direction. In other words, the gas from the exhaust hole 33a_24 far from the exhaust outlet 4a flows through the internal flow passage FP3 to approach the exhaust outlet 4a. This can avoid an increase in the route length from the exhaust hole 33a_24 to the exhaust outlet 4a.

In the example of FIG. 4, the exhaust holes 32a at the second tier are arranged at every other position in regions each of which is defined by adjacent two of the exhaust holes 33a at the third tier. This allows, for example, gases flowing into the exhaust hole 33a_11 and the exhaust hole33a_12 at the third tier to flow through the internal flow passage FP3 toward the exhaust hole 32a_11 at the second tier from mutual opposite sides. Thus, the route length from the exhaust hole 33a_11 at the third tier to the exhaust hole 32a_11 at the second tier can be brought closer to the route length from the exhaust hole 33a_12 at the third tier to the exhaust hole 32a_11 at the second tier. When the exhaust hole 32a_11 at the second tier is equidistant to the exhaust hole 33a_11 and the exhaust hole 33a_12 at the third tier, these route lengths can be matched to each other. Similarly, gases flowing into the exhaust hole 33a_13 and the exhaust hole 33a_14 at the third tier flow through the internal flow passage FP3 toward the exhaust hole 32a_12 at the second tier from mutual opposite sides. The same applies to the exhaust hole 33a_21 to the exhaust hole 33a_24 at the third tier.

As described above, variations in the route length of the gas in the internal flow passage FP3 can effectively be reduced when two to the power of n (= 8) exhaust holes 33a at the n (= 3)-th tier are arranged in the circumferential direction, two to the power of (n – 1) (= 4) exhaust holes 32a at the (n – 1) (= 2)-th tier are arranged in the circumferential direction, and the exhaust holes 32a at the (n – 1)-th tier are arranged at every other position in the regions each of which is defined by adjacent two of the exhaust holes 33a at the n-th tier. The variations in the route length of the gas in the internal flow passage FP3 can almost be eliminated when the exhaust holes 33a are arranged at equal intervals, the exhaust holes 32a are arranged at equal intervals, and each of the exhaust holes 32a is located at the center between corresponding two of the exhaust holes 33a.

Next, the internal flow passage FP2 at the second tier will be described. In the example of FIG. 1, the internal flow passage FP2 is formed by the flow passage components 32 at the second tier and the flow passage component 31 at the first tier. Lower ends of the inner circumferential wall 42 and the outer circumferential wall 43 of the flow passage component 32 at the second tier can be in contact with the flow passage component 31 (specifically, the plate portion 41) at the first tier. The flow passage component 32 at the second tier may be placed on the flow passage component 31 at the first tier, and may be fixed to the flow passage component 31. In the example of FIG. 6, the flow passage component 31 at the first tier also includes the plate portion 41, the inner circumferential wall 42, and the outer circumferential wall 43. The plate portion 41 of the flow passage component 31 functions as a partition part for partitioning the internal flow passage FP2 at the second tier and the internal flow passage FP1 at the first tier. The plurality of exhaust holes 31a are formed in the plate portion 41 of the flow passage component 31. The exhaust holes 31a penetrate the plate portion 41 of the flow passage component 31 in the vertical direction. Each of the exhaust holes 31a functions as an opening that connects the internal flow passage FP2 to the internal flow passage FP1.

In the example of FIG. 6, all the exhaust holes 31a are located at positions clear of the exhaust outlet 4a in a plan view. In other words, none of the exhaust holes 31a overlaps the exhaust outlet 4a in a plan view in the example of FIG. 6. In the example of FIG. 6, the exhaust holes 31a are arranged at equal intervals in the circumferential direction. In the example of FIG. 6, the exhaust holes 31a at the first tier are fewer in number than the exhaust holes 32a at the second tier. The number of the exhaust holes 31a is two as a specific example. In other words, the number of the exhaust holes 31a at the n (= 1)-th tier is two to the power of n (= 2) in the example of FIG. 6.

In the example of FIG. 6, an exhaust hole 31a_11 that is one exhaust hole 31a is provided in the first arc region R1, and an exhaust hole 31a_21 that is one exhaust hole 31a is provided in the second arc region R2.

In the example of FIG. 5, the exhaust holes 31a at the first tier and the exhaust holes 32a at the second tier are provided at different positions in a plan view. Furthermore, all the exhaust holes 31a at the first tier are disposed at positions clear of a region between the exhaust holes 32a_11 and the exhaust hole 32a_21 at the second tier in the example of FIG. 5. In other words, the exhaust hole 31a_11 at the first tier is provided opposite to the exhaust outlet 4a with respect to the exhaust hole 32a_11 at the second tier in the first arc region R1, and the exhaust hole 31a_21 at the first tier is provided opposite to the exhaust outlet 4a with respect to the exhaust hole 32a_21 at the second tier in the second arc region R2. Furthermore, all the exhaust holes 31a at the first tier are disposed at positions clear of a region between the exhaust holes 32a_12 and the exhaust hole 32a_22 at the second tier in the example of FIG. 5. In other words, the exhaust hole 31a_11 at the first tier is provided between the exhaust hole 32a_11 and the exhaust hole 32a_12 at the second tier in the first arc region R1, and the exhaust hole 31a_21 at the first tier is provided between the exhaust hole 32a_21 and the exhaust hole 32a_22 at the second tier in the second arc region R2 in the example of FIG. 5. As a specific example, the exhaust hole 31a_11 at the first tier is located at the center between the exhaust hole 32a_11 and the exhaust hole 32a_12 at the second tier, and the exhaust hole 31a_21 at the first tier is located at the center between the exhaust hole 32a_21 and the exhaust hole 32a_22 at the second tier. Thus, the exhaust holes 31a at the first tier are arranged at every other position in regions each of which is defined by adjacent two of the four exhaust holes 32a at the second tier.

This allows the gas flowing into the exhaust hole 32a_11 at the second tier to flow through the internal flow passage FP2 toward the exhaust hole 31a_11 at the first tier in the circumferential direction. In other words, the gas from the exhaust hole 32a_11 closer to the exhaust outlet 4a flows away from the exhaust outlet 4a through the internal flow passage FP2. This can extend the route length from the exhaust hole 32a_11 to the exhaust outlet 4a. Similarly, the gas flowing into the exhaust hole 32a_21 at the second tier flows through the internal flow passage FP2 toward the exhaust hole 31a_21 at the first tier in the circumferential direction. In other words, the gas from the exhaust hole 32a_21 closer to the exhaust outlet 4a flows away from the exhaust outlet 4a through the internal flow passage FP2. This can extend the route length from the exhaust hole 32a_21 to the exhaust outlet 4a.

Furthermore, the gas flowing into the exhaust hole 32a_12 at the second tier flows through the internal flow passage FP2 toward the exhaust hole 32a_11 at the first tier in the circumferential direction. In other words, the gas from the exhaust hole 32a_12 far from the exhaust outlet 4a flows through the internal flow passage FP2 to approach the exhaust outlet 4a. This can avoid an increase in the route length from the exhaust hole 32a_12 to the exhaust outlet 4a. Similarly, the gas flowing into the exhaust hole 32a_22 at the second tier flows through the internal flow passage FP2 toward the exhaust hole 31a_21 at the first tier in the circumferential direction. In other words, the gas from the exhaust hole 32a_22 far from the exhaust outlet 4a flows through the internal flow passage FP2 to approach the exhaust outlet 4a. This can avoid an increase in the route length from the exhaust hole 32a_22 to the exhaust outlet 4a.

As described in the specific example of FIG. 5, variations in the route length of the gas in the internal flow passage FP2 can effectively be reduced when two to the power of n (= 4) exhaust holes 32a at the n (= 2)-th tier are arranged in the circumferential direction, two to the power of (n – 1) (= 2) exhaust holes 31a at the (n – 1) (= 1)-th tier are arranged in the circumferential direction, and the exhaust holes 31a at the (n – 1)-th tier are arranged at every other position in the regions each of which is defined by adjacent two of the exhaust holes 32a at the n-th tier. The variations in the route length of the gas in the internal flow passage FP2 can almost be eliminated when the exhaust holes 32a are arranged at equal intervals, the exhaust holes 31a are arranged at equal intervals, and each of the exhaust holes 31a is disposed at the center between corresponding two of the exhaust holes 32a.

Next, the internal flow passage FP1 at the first tier will be described. In the example of FIG. 1, the internal flow passage FP1 is formed by the flow passage component 31 at the first tier and a part of the bottom of the chamber 10. In other words, the exhaust duct component 5 also includes the part of the bottom of the chamber 10. The exhaust outlet 4a is formed at the part of the bottom of the chamber 10. The exhaust outlet 4a is aligned in the vertical direction with a part of the flow passage components 3 in the circumferential direction.

The exhaust outlet 4a is located at the center between the exhaust hole 31a_11 and the exhaust hole 31a_21 in a plan view. The gas from the exhaust hole 31a_11 flows toward the exhaust outlet 4a through the internal flow passage FP1. The gas from the exhaust hole 31a_21 also flows toward the exhaust outlet 4a through the internal flow passage FP1. In other words, the gas flows through the internal flow passage FP1 to approach the exhaust outlet 4a. When the exhaust outlet 4a is located at the center between the exhaust hole 31a_11 and the exhaust hole 31a_21, the route lengths of the gas in the internal flow passage FP1 can be ideally made equal to each other.

As described above, the gas supplied to the main surface Wa of the substrate W flows into the exhaust holes 30a of the exhaust duct component 5. The respective gases flow through the internal flow passages FP in order from the upstream tier to the downstream tier and flow into the exhaust outlet 4a. In Embodiment 1, the gas flowing into the exhaust hole 30aa that is the closest to the exhaust outlet 4a among the exhaust holes 30a at the most upstream tier flows away from the exhaust outlet 4a through at least one of the internal flow passages FP. In the aforementioned examples, the gas from the exhaust hole 30aa flows away from the exhaust outlet 4a through each of the internal flow passages FP from the most upstream tier to the second tier. This can extend the route length from the exhaust hole 30aa that is the closest to the exhaust outlet 4a to the exhaust outlet 4a. Thus, variations in the route lengths from the exhaust holes 30a to the exhaust outlet 4a can be reduced. Further, variations in the flow velocity distribution of the gas flowing along the main surface Wa of the substrate W can be reduced.

In the aforementioned examples, the gas flowing into the exhaust hole 30ab that is the furthest from the exhaust outlet 4a among the exhaust holes 30a at the most upstream tier flows through all the internal flow passages FP from the most upstream tier to the first tier to approach the exhaust outlet 4a. Thus, variations in the route lengths from the exhaust holes 30a to the exhaust outlet 4a can further be reduced.

Furthermore, the gas flowing into the exhaust hole 3a closer to the exhaust outlet 4a may flow away from the exhaust outlet 4a through each of the internal flow passages FP at the second tier and above. In the specific examples above, the gas flowing into the exhaust hole 33a_11 at the third tier flows away from the exhaust outlet 4a through the internal flow passage FP3 at the third tier, and the gas flowing into the exhaust hole 32a_11 at the second tier flows away from the exhaust outlet 4a through the internal flow passage FP2 at the second tier. This can further reduce variations in the route lengths from the exhaust holes 3a to the exhaust outlet 4a. Similarly, the gas flowing into the exhaust hole 3a that is the furthest from the exhaust outlet 4a at each of the tiers may flow through all the internal flow passages FP at lower ones of the tiers to approach the exhaust outlet 4a. This can further reduce variations in the route lengths from the exhaust holes 3a to the exhaust outlet 4a.

For example, the number of the exhaust holes 3a may be reduced as a tier to which the exhaust holes 3a belong is located more downstream. Furthermore, all of the exhaust hole(s) 3a at the (n - 1)-th tier may be provided between the exhaust hole 3a the closest to the exhaust outlet 4a and the exhaust hole 3a the furthest from the exhaust outlet 4a among the exhaust holes 3a at the n-th tier in the first arc region R1. Consequently, the gas flowing into the exhaust holes 3a at the n-th tier that is the closest to the exhaust outlet 4a can flow away from the exhaust outlet 4a through the internal flow passage FP at the n-th tier. Furthermore, the gas flowing into the exhaust hole 3a at the n-th tier that is the furthest from the exhaust outlet 4a can flow through the internal flow passage FP at the n-th tier to approach the exhaust outlet 4a.

As a specific example, the number of the exhaust holes 3a at the n-th tier (except the most upstream tier) may be two to the power of n, and the exhaust holes 3a at the n-th tier may be arranged at every other position in the regions each of which is defined by adjacent two of the exhaust holes 3a at the (n + 1)-th tier. Consequently, variations in the route length can effectively be reduced.

Furthermore, the exhaust holes 3a at the n-th tier (except the most upstream tier) may be arranged at equal intervals in the circumferential direction, and each of the exhaust holes 3a may be provided at the center between adjacent two of the exhaust holes 3a at the (n + 1)-th tier. Consequently, variations in the route length can ideally be eliminated.

In the aforementioned examples, the number of the exhaust holes 3a at the n-th tier except the most upstream tier is two to the power of n. Additionally, the number of the exhaust holes 3a at each of at least two tiers that are consecutively arranged in the vertical direction may be two to the power of n. In each of the at least two tiers, the exhaust holes 3a at a downstream tier may be arranged at every other position in the regions each of which is defined by adjacent two of the exhaust holes 3a at a tier immediately upstream of the downstream tier.

In the aforementioned specific examples, the flow passage component 3 at each of the tiers except the most upstream tier includes the ring-shaped plate portion 41, the inner circumferential wall 42, and the outer circumferential wall 43. With this, the inner circumferential wall 42 and the outer circumferential wall 43 are supported by the plate portion 41 at a lower tier. This facilitates stacking the flow passage components 3.

Next, an example of a specific shape of the exhaust hole 3a will be described. In the examples of FIGS. 4 to 6, each of the exhaust holes 3a at the n-th tier (except the most upstream tier) has a long shape longer in the radial direction. In other words, the width of the exhaust hole 3a in the radial direction is greater than that in the circumferential direction. Put it differently, the exhaust hole 3a is an open slit whose radial direction is a longitudinal direction. The width of the exhaust hole 3a in the circumferential direction may be less than the thickness of the plate portion 41 of the flow passage component 3. The width of the exhaust hole 3a in the radial direction may be one half, two third, three fourth, or four fifth or more of a difference between an outer diameter and an inner diameter of the internal flow passage FP, or may be as large as the difference.

A case where the exhaust holes 3a are holes longer in the circumferential direction will be described for comparison. In this case, a length between one of the ends and the other end of the exhaust hole 3a in the circumferential direction is greater. Unfortunately, a difference between a route length from one end of the exhaust hole 3a at the n-th tier to the exhaust hole 3a at the next (n – 1)-th tier and a route length from the other end to the exhaust hole 3a at the next (n – 1)-th tier becomes relatively larger. Such an increase in the difference in the route length tends to cause variations in the gas flow.

In contrast, when the width of the exhaust hole 3a in the circumferential direction is less as described above, such variations in the gas flow can be reduced. This allows a gas to more uniformly flow through the internal flow passages FP. When the width of the exhaust hole 3a in the radial direction is, for example, four fifth or more of a difference between the outer diameter and the inner diameter of the internal flow passage FP, variations in the distribution of gas flows in the radial direction can effectively be reduced.

In the example of FIG. 2, each of the exhaust holes 3a at the most upstream tier is of a circular shape in a plan view. This can make the flow velocity distribution of the gases flowing in the radial direction along the main surface Wa of the substrate W more uniform.

### Embodiment 2

With reference to FIG. 7, regions in which a gas hardly flows exist in the internal flow passages FP except at the most upstream tier. In the example of FIG. 7, these regions are schematically illustrated by dashed lines. For example, a region between the exhaust hole 33a_12 and the exhaust hole 33a_13 in the internal flow passage FP3 at the third tier does not include the exhaust hole 32a at the next second tier. Thus, a gas rarely flows through this region. In other words, the gas tends to be retained in the region. Generally speaking, the gas rarely flows through a region without the exhaust hole 3a at the (n – 1)-th tier, in the regions each of which is defined by adjacent two of the exhaust holes 3a at the n-th tier. If a processing gas in the chamber 10 flows into the region, the processing gas is unfortunately retained in the region. Embodiment 2 intends to reduce retention of the gas in the internal flow passages FP.

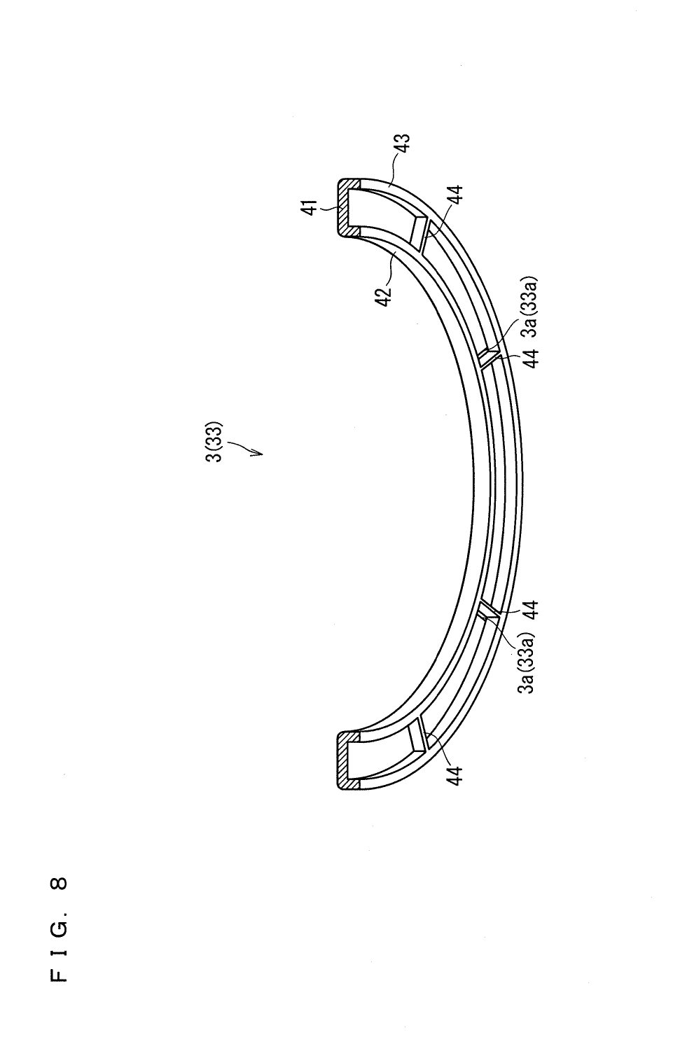

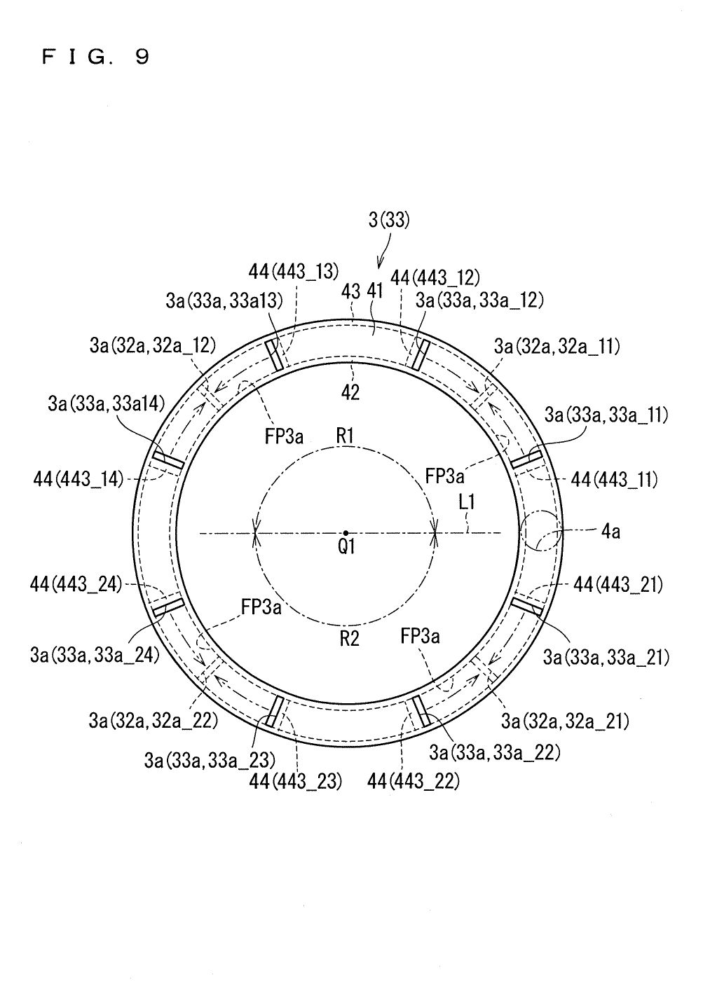

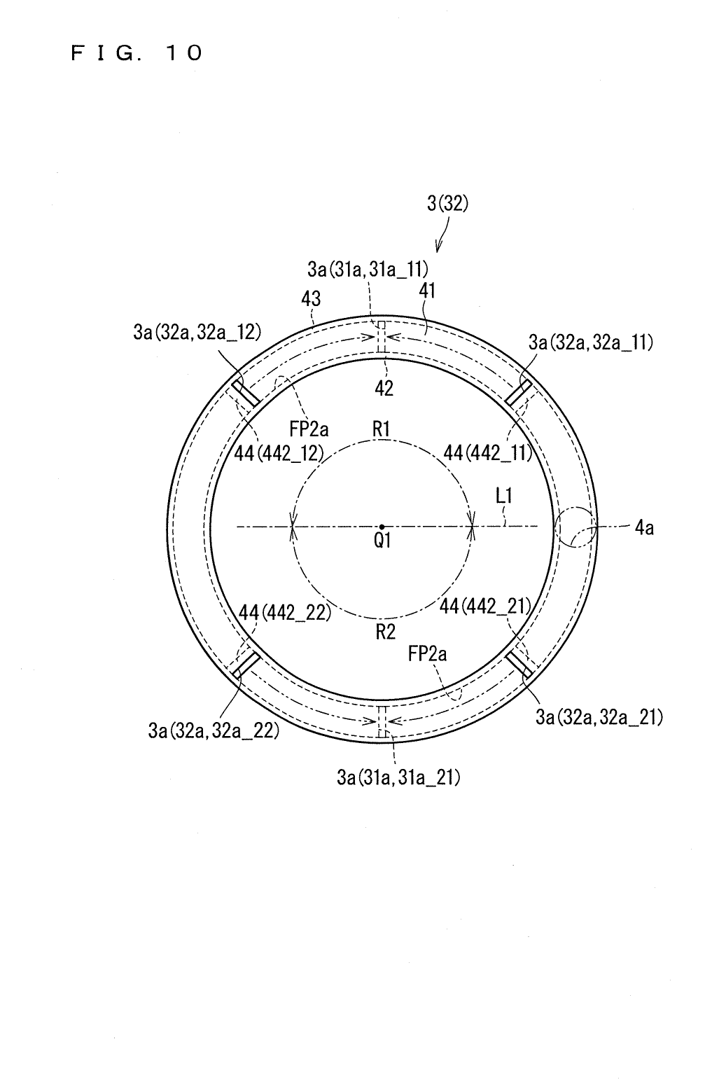

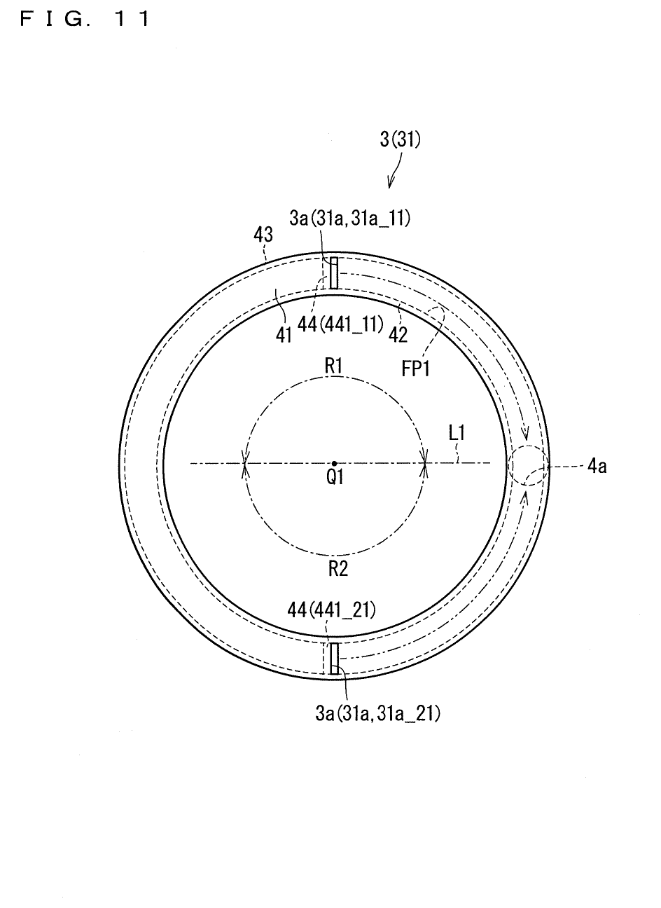

FIG. 8 is a perspective view schematically illustrating a first example structure of a part of the flow passage component 3 according to Embodiment 2. FIG. 9 is a plan view schematically illustrating the first example structure of the flow passage component 33 according to Embodiment 2. FIG. 10 is a plan view schematically illustrating the first example structure of the flow passage component 32 according to Embodiment 2. FIG. 11 is a plan view schematically illustrating the first example structure of the flow passage component 31 according to Embodiment 2.

As illustrated in FIG. 8, the flow passage component 3 includes a plurality of partition walls 44 in addition to the plate portion 41, the inner circumferential wall 42, and the outer circumferential wall 43. In the example of FIG. 9, the flow passage component 33 at the third tier includes eight partition walls 44. The partition walls 44 are components for partitioning the internal flow passage FP in the circumferential direction. For example, the partition walls 44 at the third tier partition the internal flow passage FP into four divided flow passages FP3a. In other words, the internal flow passage FP at the third tier includes the divided flow passages FP3a that are separated in the circumferential direction. For example, the number of the divided flow passages FP3a at the n (= 3)-th tier is two to the power of (n – 1) (= 4).

Each of the partition walls 44 is connected to the plate portion 41, the inner circumferential wall 42, and the outer circumferential wall 43. The partition wall 44 is, for example, plate-shaped, and is disposed in an attitude such that its thickness direction is along the circumferential direction. A lower end of each of the partition walls 44 at the n-th tier may be connected to the flow passage component 3 at the (n – 1)-th tier immediately downstream of the n-th tier. In the example of FIG. 9, four partition walls 44 are located in the first arc region R1, and the other four partition walls 44 are located in the second arc region R2. Hereinafter, the four partition walls 44 in the first arc region R1 may be referred to as a partition wall 443_11 to a partition wall 443_14, and the four partition walls 44 in the second arc region R2 may be referred to as a partition wall 443_21 to a partition wall 443_24.

As illustrated in FIG. 9, the partition wall 443_11 to the partition wall 443_14 are provided in order of proximity to the exhaust outlet 4a. The partition wall 443_11 is located opposite to the exhaust hole 32a_11 at the second tier with respect to the exhaust hole 33a_11 at the third tier. The partition wall 443_11 may be in close proximity to the exhaust hole 33a_11. The partition wall 443_12 is located opposite to the exhaust hole 32a_11 at the second tier with respect to the exhaust hole 33a_12 at the third tier. The partition wall 443_12 may be in close proximity to the exhaust hole 33a_12. The partition wall 443_11 and the partition wall 443_12 define ends of the divided flow passage FP3a in the circumferential direction. The divided flow passage FP3a includes the exhaust hole 33a_11 at the third tier, the exhaust hole 33a_12 at the third tier, and the exhaust hole 32a_11 at the second tier.

The partition wall 443_13 is located opposite to the exhaust hole 32a_12 at the second tier with respect to the exhaust hole 33a_13 at the third tier. The partition wall 443_13 may be in close proximity to the exhaust hole 33a_13. The partition wall 444_14 is located opposite to the exhaust hole 32a_12 at the second tier with respect to the exhaust hole 33a_14 at the third tier. The partition wall 444_14 may be in close proximity to the exhaust hole 33a_14. The partition wall 443_13 and the partition wall 443_14 define ends of the divided flow passage FP3a in the circumferential direction. The divided flow passage FP3a includes the exhaust hole 33a_13 at the third tier, the exhaust hole 33a_14 at the third tier, and the exhaust hole 32a_12 at the second tier.

A position relationship between the partition wall 443_21 to the partition wall 443_24 and the exhaust holes 3a in the second arc region R2 is identical to a position relationship between the partition wall 443_11 to the partition wall 443_14 and the exhaust holes 3a in the first arc region R1.

As described above, the partition walls 44 form the four divided flow passages FP3a at the third tier. In other words, a pair of the partition walls 44 defines both ends of the divided flow passage FP3a in the circumferential direction, and the exhaust holes 33a at the third tier are located near the ends of each of the divided flow passages FP3a. Furthermore, the exhaust hole 32a at the second tier is located at the center of the divided flow passage FP3a. Thus, the gas flowing into each of the exhaust holes 33a hardly flows toward the partition walls 44, and can promptly flow toward the exhaust hole 32a at the next tier. Thus, the possibility that the processing gas in the chamber 10 is retained in the divided flow passages FP3a can be reduced. When each of the exhaust holes 33a is adjacent to the partition wall 44 corresponding to the exhaust hole 33a, the possibility of retention of the processing gas in the divided flow passages FP3a can be reduced the most.

In the example of FIG. 10, the flow passage component 32 at the second tier includes four partition walls 44. The partition walls 44 are components for partitioning the internal flow passage FP2 at the second tier into two divided flow passages FP2a. In other words, the internal flow passage FP2 at the second tier includes the two divided flow passages FP2a that are separated in the circumferential direction. In other words, the number of the divided flow passages FP2a at the n (= 2)-th tier is two to the power of (n – 1) (= 2). In the example of FIG. 10, two of the four partition walls 44 are located in the first arc region R1, and the other two partition walls 44 are located in the second arc region R2. Hereinafter, the two partition walls 44 in the first arc region R1 may be referred to as a partition wall 442_11 and a partition wall 442_12, and the two partition walls 44 in the second arc region R2 may be referred to as a partition wall 442_21 and a partition wall 442_22.

As illustrated in FIG. 10, the partition wall 442_11 and the partition wall 442_12 are provided in order of proximity to the exhaust outlet 4a. The partition wall 442_11 is located opposite to the exhaust hole 31a_11 at the first tier with respect to the exhaust hole 32a_11 at the second tier. The partition wall 442_11 may be in close proximity to the exhaust hole 32a_11. The partition wall 442_12 is located opposite to the exhaust hole 31a_11 at the first tier with respect to the exhaust hole 32a_12 at the second tier. The partition wall 442_12 may be in close proximity to the exhaust hole 32a_12. The partition wall 442_11 and the partition wall 442_12 define ends of the divided flow passage FP2a in the circumferential direction. The divided flow passage FP2a includes the exhaust hole 32a_11 at the second tier, the exhaust hole 32a_12 at the second tier, and the exhaust hole 31a_11 at the first tier.

A position relationship between the partition wall 442_21, the partition wall 442_22, and the exhaust holes 3a in the second arc region R2 is identical to a position relationship between the partition wall 442_11, the partition wall 442_12, and the exhaust holes 3a in the first arc region R1.

As described above, a pair of the partition walls 44 defines both ends of the divided flow passage FP2a in the circumferential direction also at the second tier, and the exhaust holes 32a at the second tier are located near the ends of the divided flow passage FP2a. Furthermore, the exhaust hole 31a at the first tier is located at the center of the divided flow passage FP2a. Thus, the possibility that the processing gas in the chamber 10 is retained in the divided flow passages FP2a can be reduced, similarly to the divided flow passages FP3a.

In the example of FIG. 11, the flow passage component 31 at the first tier includes two partition walls 44. The partition walls 44 are components for defining ends of the internal flow passage FP1 at the first tier in the circumferential direction. The number of the internal flow passage FP1 at the n (= 1)-th tier is two to the power of (n – 1) (= 1). One of the two partition walls 44 is located in the first arc region R1, and the other one partition wall 44 is located in the second arc region R2. Hereinafter, the partition wall 44 in the first arc region R1 may be referred to as a partition wall 441_11, and the partition wall 44 in the second arc region R2 may be referred to as a partition wall 441_21.

The partition wall 441_11 is located opposite to the exhaust outlet 4a with respect to the exhaust hole 31a_11 at the first tier. The partition wall 441_11 may be in close proximity to the exhaust hole 31a_11. The partition wall 441_21 is located opposite to the exhaust outlet 4a with respect to the exhaust hole 31a_21 at the first tier. The partition wall 441_21 may be in close proximity to the exhaust hole 31a_21. The partition wall 441_11 and the partition wall 441_21 define ends of the internal flow passage FP1 in the circumferential direction. The internal flow passage FP1 includes the exhaust hole 31a_11 at the first tier, the exhaust hole 31a_21 at the first tier, and the exhaust outlet 4a.

As described above, a pair of the partition walls 44 defines both ends of the internal flow passage FP1 in the circumferential direction also at the first tier, and the exhaust holes 31a at the first tier are located near the ends of the internal flow passage FP1. Furthermore, the exhaust outlet 4a is located at the center of the internal flow passage FP1. Thus, the possibility that the processing gas in the chamber 10 is retained in the internal flow passage FP1 can be reduced, similarly to the divided flow passages FP2a.

In the aforementioned examples, each of the flow passage components 3 except at the most upstream tier includes the ring-shaped plate portion 41, the inner circumferential wall 42, the outer circumferential wall 43, and the partition walls 44. These facilitate stacking the flow passage components 3 also in Embodiment 2.

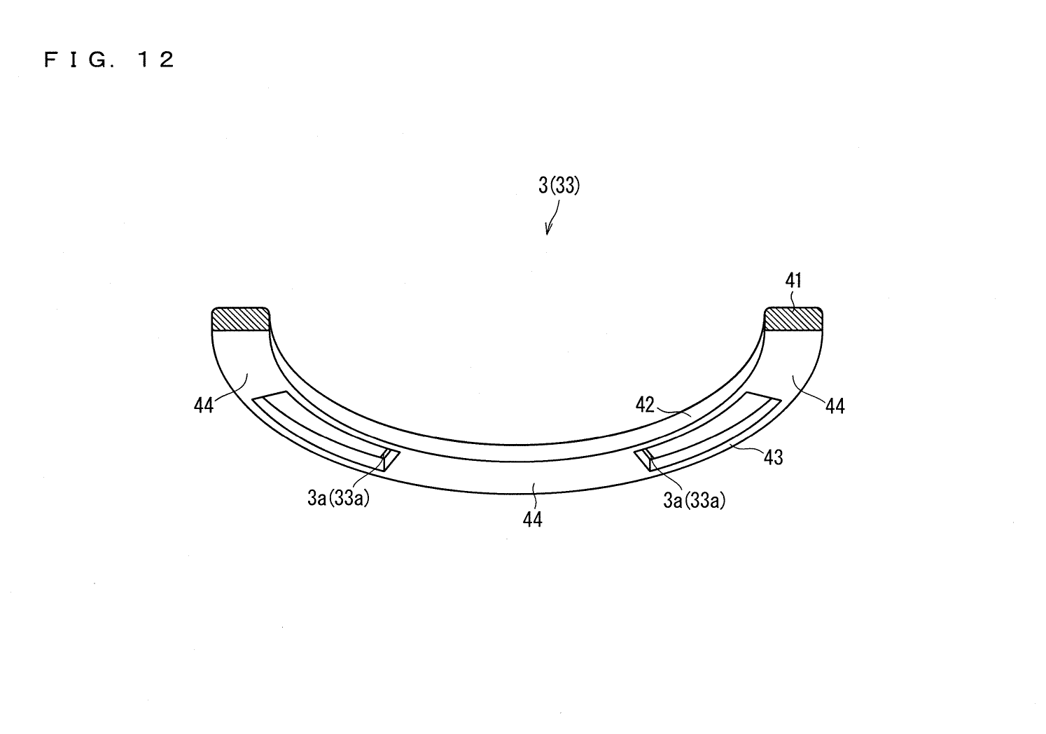

FIG. 12 is a perspective view schematically illustrating the second example structure of a part of the flow passage component 3 according to Embodiment 2. In the example of FIG. 12, the width of each of the partition walls 44 in the circumferential direction is greater than that of the first example, and the partition wall 44 defines facing ends of the adjacent two internal flow passages FP in the circumferential direction. For example, the number of the partition walls 44 in the flow passage component 3 at the n-th tier is two to the power of (n – 1). Both ends of each of the partition walls 44 in the circumferential direction define the ends of the adjacent two internal flow passages FP in the circumferential direction. This can also reduce the possibility of retention of the gas in the internal flow passages FP.

### Embodiment 3

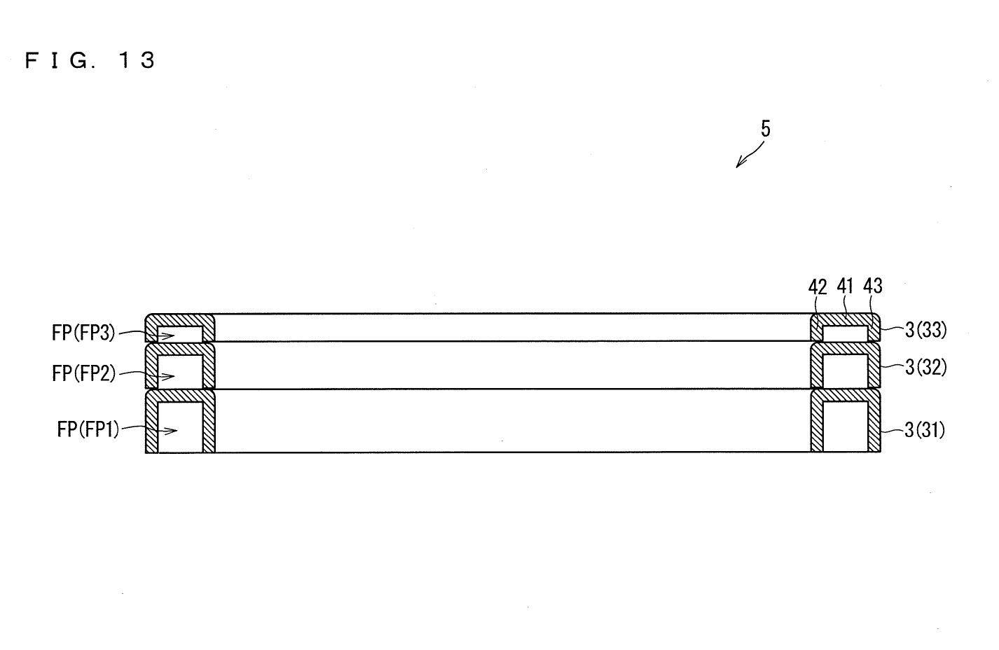

FIG. 13 is a cross-sectional view schematically illustrating an example structure of the flow passage components 3 according to Embodiment 3. The flow passage components 3 according to Embodiment 3 differ from those according to Embodiment 1 or 2 in size in the vertical direction.

The height width of the internal flow passage FP is greater as a tier to which the internal flow passage FP belongs is located more downstream in Embodiment 3. In other words, the size of the flow passage component 3 at the (n – 1)-th tier is greater than that at the n-th tier in the vertical direction. In other words, the inner circumferential wall 42 and the outer circumferential wall 43 are greater in height width as a tier to which the inner circumferential wall 42 and the outer circumferential wall 43 belong is located more downstream. For example, the height width of the internal flow passage FP at the (n – 1)-th tier may be 1.5 times larger than or equal to or approximately twice the height width of the internal flow passage FP at the n-th tier.

Similarly to Embodiments 1 and 2, the gas flowing through the immediately previous internal flow passage FP merges and flows into the exhaust holes 3a at each of the tiers also in Embodiment 3. In other words, a larger amount of gas flows through the internal flow passage FP as a tier to which the internal flow passage FP belongs is located more downstream. Since the size of the internal flow passage FP in the vertical direction is greater as a tier to which the internal flow passage FP belongs is located more downstream in Embodiment 3, a larger amount of gas can easily flow through the internal flow passage FP at a downstream tier. Conversely speaking, reduction in size of the internal flow passage FP at an upstream tier in the vertical direction can reduce the overall size of the exhaust duct component 5 in the vertical direction.

The present disclosure includes the following aspects.

A first aspect is an exhaust duct component disposed around a substrate mounting part supporting or holding a substrate, the exhaust duct component including flow passage components at N tiers, N being a natural number larger than or equal to 2, the flow passage components being disposed around the substrate mounting part in a plan view, the flow passage components forming respective internal flow passages into each of which a gas flows, each of the flow passage components at the N tiers including a plurality of exhaust holes through which the gas flows into the internal flow passages, the exhaust holes of each of the flow passage components at the N tiers being arranged in a circumferential direction around the substrate mounting part in the plan view, the exhaust duct component including an exhaust outlet connected to a corresponding one of the internal flow passages at a most downstream tier among the N tiers, wherein the gas flowing from an exhaust hole closest to the exhaust outlet in the plan view among the exhaust holes at a most upstream tier among the N tiers flows away from the exhaust outlet through at least one of the internal flow passages at the N tiers in the circumferential direction.

A second aspect is the exhaust duct component according to the first aspect, wherein the number of the exhaust holes in each of the flow passage components at the N tiers is less as a tier to which the exhaust holes belong among the N tiers is located more downstream.

A third aspect is the exhaust duct component according to the first or second aspect, wherein the exhaust holes at an n-th tier and the exhaust holes at an (n – 1)-th tier are provided at different positions in the plan view, n being a natural number larger than or equal to 2.

A fourth aspect is the exhaust duct component according to the third aspect, wherein the number of the exhaust holes at the n-th tier is two to the power of n, the number of the exhaust holes at the (n – 1)-th tier is two to the power of (n – 1), and the exhaust holes at the (n – 1)-th tier are arranged at every other position in regions each of which is defined by adjacent two of the exhaust holes at the n-th tier in the plan view.

A fifth aspect is the exhaust duct component according to the fourth aspect, wherein the internal flow passage at the n-th tier includes two to the power of (n – 1) divided flow passages arranged in the circumferential direction, and each of the divided flow passages at the n-th tier includes two of the exhaust holes at the n-th tier and one of the exhaust holes at the (n – 1)-th tier.

A sixth aspect is the exhaust duct component according to the fifth aspect, wherein the flow passage component at the n-th tier includes: a plate portion which is ring-shaped and in which two to the power of n exhaust holes are formed, the plate portion surrounding the substrate mounting part; an inner circumferential wall provided at an inner circumferential end portion of the plate portion; an outer circumferential wall provided at an outer circumferential end portion of the plate portion; and partition walls partitioning a space into the divided flow passages in the circumferential direction, the space being enclosed by the plate portion, the inner circumferential wall, and the outer circumferential wall.

A seventh aspect is the exhaust duct component according to any one of the first to sixth aspects, wherein each of the exhaust holes of the flow passage component at an n-th tier has a long shape whose width in a radial direction is greater than a width of the long shape in the circumferential direction.

An eighth aspect is the exhaust duct component according to the seventh aspect, wherein the width of the long shape in the circumferential direction is less than a thickness of a portion of the flow passage component in which the exhaust holes are formed.

A ninth aspect is the exhaust duct component according to any one of the first to eighth aspects, wherein a height width of each of the internal flow passages is greater as a tier to which the internal flow passage belongs among the N tiers is located more downstream.

A tenth aspect is a substrate processing apparatus including: a chamber; the exhaust duct component according to any one of the first to ninth aspects which is disposed in the chamber; the substrate mounting part disposed in the chamber; a gas supply part that supplies a gas to the chamber; and an exhaust part that discharges the gas in the chamber through the exhaust outlet.

The first to third and tenth aspects can reduce the variations in the lengths of the gas routes from the exhaust holes at the most upstream tier to the exhaust outlet. This allows the gas to more uniformly flow.

The fourth aspect can further reduce the variations in the route length.

The fifth aspect can reduce the possibility of retention of the gas in the internal flow passage.

The sixth aspect facilitates stacking the flow passage components.

The seventh aspect allows the gas to more uniformly flow through the internal flow passage at the n-th tier.

The eighth aspect allows the gas to more uniformly flow.

The ninth aspect allows the gas to easily flow while reducing the size of the exhaust duct component.

What is claimed is:

1. An exhaust duct component disposed around a substrate mounting part supporting or holding a substrate, the exhaust duct component comprising
flow passage components at N tiers, N being a natural number larger than or equal to 2, the flow passage components being disposed around the substrate mounting part in a plan view, the flow passage components forming respective internal flow passages into each of which a gas flows, each of the flow passage components at the N tiers including a plurality of exhaust holes through which the gas flows into the internal flow passages, the exhaust holes of each of the flow passage components at the N tiers being arranged in a circumferential direction around the substrate mounting part in the plan view, the exhaust duct component comprising an exhaust outlet connected to a corresponding one of the internal flow passages at a most downstream tier among the N tiers, wherein the gas flowing from an exhaust hole closest to the exhaust outlet in the plan view among the exhaust holes at a most upstream tier among the N tiers flows away from the exhaust outlet through at least one of the internal flow passages at the N tiers in the circumferential direction.

2. The exhaust duct component according to claim 1,
wherein the number of the exhaust holes in each of the flow passage components at the N tiers is less as a tier to which the exhaust holes belong among the N tiers is located more downstream.

3. The exhaust duct component according to claim 1,
wherein the exhaust holes at an n-th tier and the exhaust holes at an (n – 1)-th tier are provided at different positions in the plan view, n being a natural number larger than or equal to 2.

4. The exhaust duct component according to claim 3,
wherein the number of the exhaust holes at the n-th tier is two to the power of n,
the number of the exhaust holes at the (n – 1)-th tier is two to the power of (n – 1), and
the exhaust holes at the (n – 1)-th tier are arranged at every other position in regions each of which is defined by adjacent two of the exhaust holes at the n-th tier in the plan view.

5. The exhaust duct component according to claim 4,
wherein the internal flow passage at the n-th tier includes two to the power of (n – 1) divided flow passages arranged in the circumferential direction, and
each of the divided flow passages at the n-th tier includes two of the exhaust holes at the n-th tier and one of the exhaust holes at the (n – 1)-th tier.

6. The exhaust duct component according to claim 5,
wherein the flow passage component at the n-th tier includes:
a plate portion which is ring-shaped and in which two to the power of n exhaust holes are formed, the plate portion surrounding the substrate mounting part;
an inner circumferential wall provided at an inner circumferential end portion of the plate portion;
an outer circumferential wall provided at an outer circumferential end portion of the plate portion; and
partition walls partitioning a space into the divided flow passages in the circumferential direction, the space being enclosed by the plate portion, the inner circumferential wall, and the outer circumferential wall.

7. The exhaust duct component according to claim 1,
wherein each of the exhaust holes of the flow passage component at an n-th tier has a long shape whose width in a radial direction is greater than a width of the long shape in the circumferential direction.

8. The exhaust duct component according to claim 7,
wherein the width of the long shape in the circumferential direction is less than a thickness of a portion of the flow passage component in which the exhaust holes are formed.

9. The exhaust duct component according to claim 1,
wherein a height width of each of the internal flow passages is greater as a tier to which the internal flow passage belongs among the N tiers is located more downstream.

10. A substrate processing apparatus, comprising:
a chamber;
the exhaust duct component according to claim 1 disposed in the chamber;
the substrate mounting part disposed in the chamber;
a gas supply part that supplies a gas to the chamber; and
an exhaust part that discharges the gas in the chamber through the exhaust outlet.
